(19) United States
(12) Patent Application Publication
(10) Pub. No.: US 2018/0219172 A1
(43) Pub. Date: Aug. 2, 2018

(54) ORGANIC EL DISPLAY DEVICE

(71) Applicant: Sharp Kabushiki Kaisha, Sakai City, Osaka (JP)

(72) Inventors: Tohru SENOO, Sakai City (JP); Takeshi HIRASE, Sakai City (JP); Tetsuya OKAMOTO, Sakai City (JP); Takashi OCHI, Sakai City (JP); Tohru SONODA, Sakai City (JP); Mamoru ISHIDA, Sakai City (JP)

(21) Appl. No.: 15/747,185

(22) PCT Filed: Aug. 18, 2016
(86) PCT No.: PCT/JP2016/003764

§ 371 Date: Jan. 24, 2018

(30) Foreign Application Priority Data
Aug. 21, 2015 (JP) 2015-164176

(51) Int. Cl. H01L 51/52; H01L 27/32; H01L 51/50

(52) U.S. Cl. CPC H01L 51/524; H01L 51/5092; H01L 51/5203; H01L 27/3211

(57) ABSTRACT

Disclosed is an organic EL display device including: a base substrate (10); an organic EL element (18) provided over the base substrate (10); and a sealing film (25a) covering the organic EL element (18). The sealing film (25a) includes a plurality of buffer layers (19a, 21a, 23a) each comprised of an inorganic film, and a buffer layer (20a, 22a) comprised of an organic film and provided between adjacent two of the plurality of buffer layers (19a, 21a, 23a). The buffer layer (20a, 22a) includes, in its peripheral edge portion surrounding the organic EL element, a flat thin portion (20t, 22t) which is thinner than the rest of the buffer layer (20a, 22a) above the organic EL element (18).

### TECHNICAL FIELD

The present invention relates to an organic EL display device.

### BACKGROUND ART

Self-luminous organic EL display devices including an organic electroluminescence (EL) element have recently received attention, as display devices alternative to liquid crystal display devices. For such organic EL display devices, a sealing structure has been proposed for reducing the deterioration of an organic EL element caused by entry of moisture, oxygen, and other substances. The sealing structure includes a sealing film covering the organic EL element and comprised of a stack of inorganic and organic films.

For example, Patent Document 1 discloses an organic EL display device including a sealing member (sealing film) formed by sequentially stacking a first barrier layer made of an inorganic material, a first buffer layer made of a resin material, a second barrier layer made of an inorganic material, a second buffer layer made of a resin material, and a third barrier layer made of an inorganic material.

### CITATION LIST

### Patent Documents

Patent Document 1: Japanese Unexamined Patent Publication No. 2006-4650

### SUMMARY OF THE INVENTION

### Technical Problem

Meanwhile, in the organic EL display device disclosed in Patent Document 1, the first, second, and third barrier layers each made of an inorganic material are stacked in a peripheral end portion of an array substrate forming part of the organic EL display device without interposing the first buffer layer made of a resin material between the first and second barrier layers, and the second buffer layer made of a resin material between the second and third layers. Therefore, stress caused by the first, second, and third barrier layers are not reduced by the first and second buffer layers in the peripheral end portion of the sealing member. Consequently, there may be the risk of deterioration of the sealing capability caused by, for example, delamination of the sealing member. In addition, in the peripheral end portion of the sealing member of the organic EL display device, if foreign matter exists at any of the interfaces between the first, second, and third barrier layers, the foreign matter is likely to break through the first, second, and third barrier layers because of the absence of the first and second buffer layers. This may deteriorate the sealing capability.

In view of the foregoing background, it is therefore an object of the present invention to reduce deterioration of sealing capability in a peripheral end portion of a sealing film.

### Solution to the Problem

To achieve the above object, an organic EL display device of the present invention includes: a base substrate defining thereon a display region configured to display an image, and a non-display region surrounding the display region; an organic EL element provided in the display region of the base substrate; and a sealing film extending over the display region and the non-display region and covering the organic EL element, the sealing film including a plurality of barrier layers each comprised of an inorganic film, and a buffer layer comprised of an organic film and provided between adjacent two of the plurality of barrier layers. The buffer layer includes, in a peripheral edge portion of the buffer layer located in the non-display region surrounding the organic EL element, a flat thin portion which is thinner than the rest of the buffer layer located above the organic EL element.

### Advantages of the Invention

According to the present invention, the buffer layer includes, in its peripheral edge portion located in the non-display region surrounding the organic EL element, the flat thin portion which is thinner than the rest of the buffer layer located above the organic EL element. This configuration can reduce deterioration of sealing capability in a peripheral end portion of the sealing film.

### BRIEF DESCRIPTION OF THE DRAWINGS

FIG. 1 is a plan view showing a schematic configuration for an organic EL display device according to a first embodiment of the present invention.

FIG. 2 is a cross-sectional view taken along line II-II in FIG. 1, showing the schematic configuration for the organic EL display device.

FIG. 3 is a cross-sectional view showing an internal configuration for the organic EL display device according to the first embodiment of the present invention.

FIG. 4 is a cross-sectional view of an organic EL layer included in the organic EL display device according to the first embodiment of the present invention.

FIG. 5 is a cross-sectional view showing a model experiment on the organic EL display device according to the first embodiment of the present invention.

FIG. 6 is a graph showing a relationship between a buffer layer thickness and a moisture osmosis distance, which was determined in the model experiment on the organic EL display device according to the first embodiment of the present invention.

FIG. 7 is a cross-sectional view showing a schematic configuration for an organic EL display device according to a second embodiment of the present invention.

FIG. 8 is a cross-sectional view showing a schematic configuration for an organic EL display device according to a third embodiment of the present invention.

### DESCRIPTION OF EMBODIMENTS

Embodiments of the present invention will now be described in detail with reference to the drawings. Note that the present invention is not limited to the following embodiments.

### First Embodiment

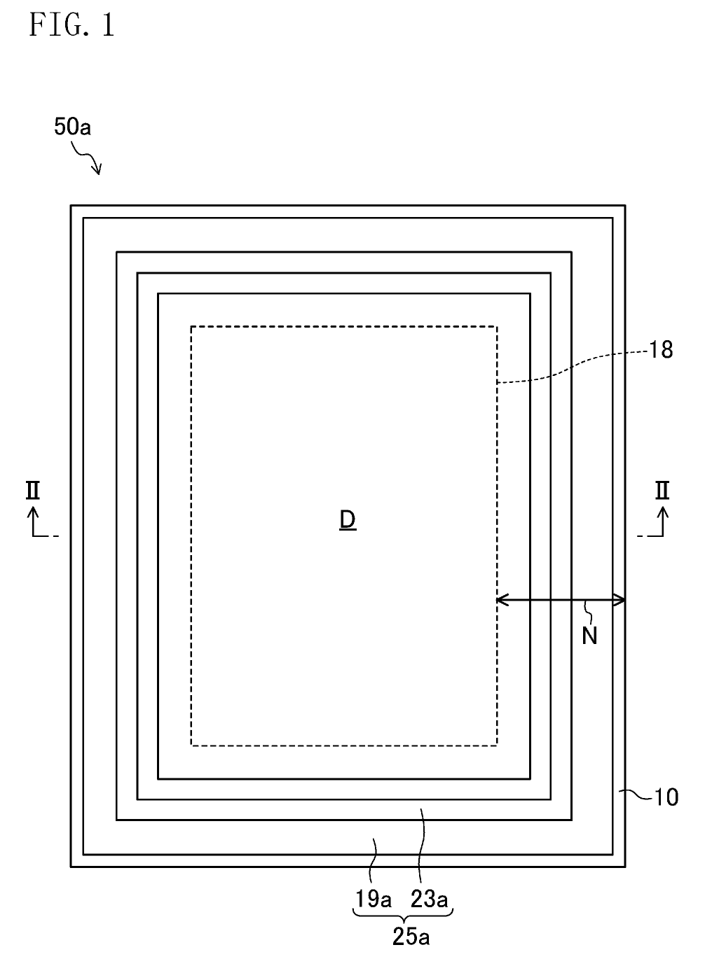

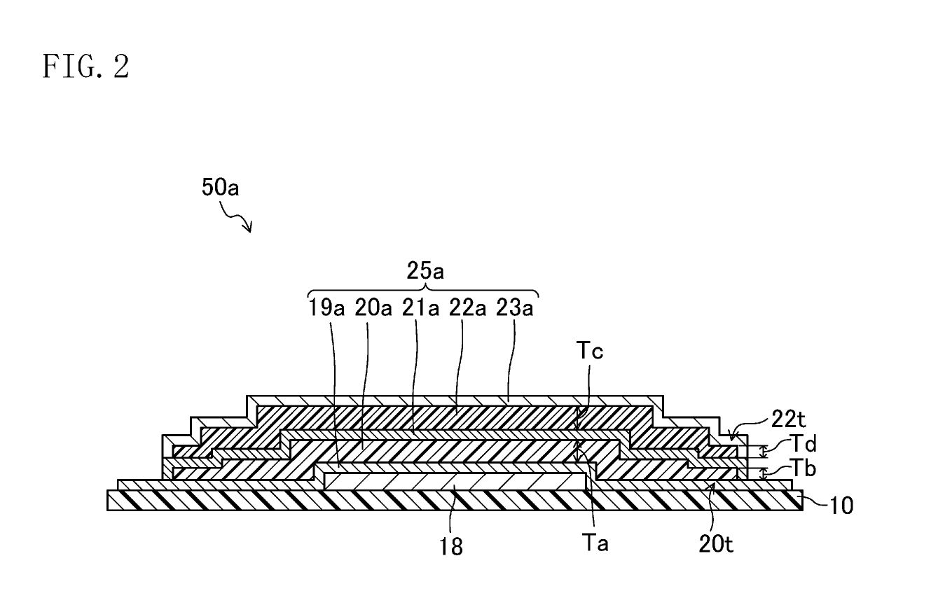

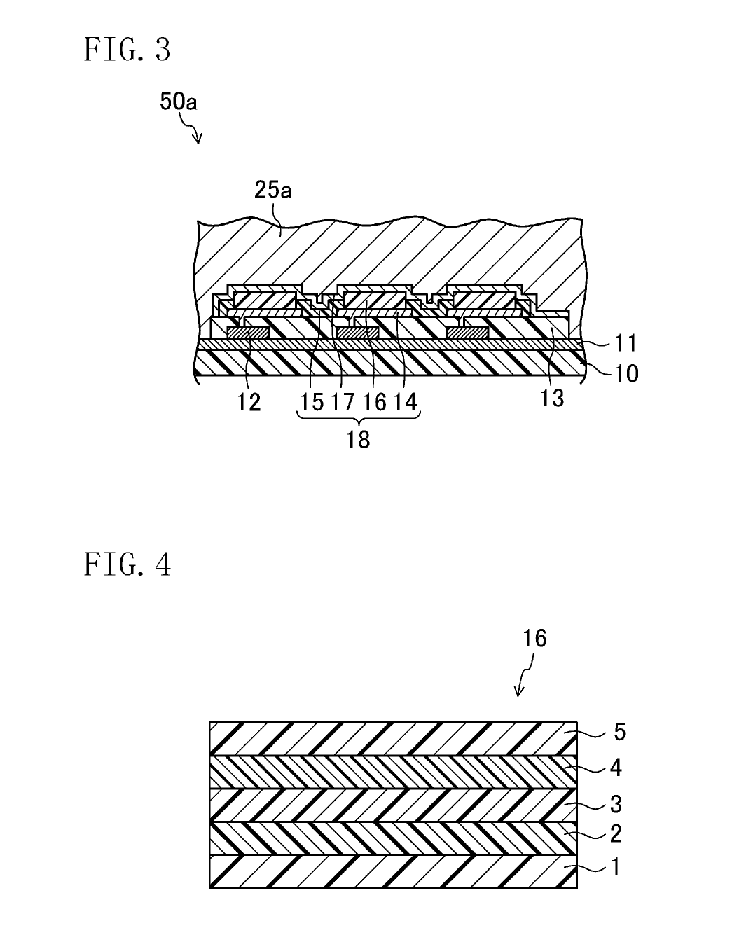

FIGS. 1-6 show a display device according to a first embodiment of the present invention. Specifically, FIG. 1 is a plan view showing a schematic configuration for the organic EL display device 50a of this embodiment. FIG. 2 is a cross-sectional view taken along line II-II in FIG. 1, showing the schematic configuration for the organic EL display device 50a. FIG. 3 is a cross-sectional view showing an internal configuration for the organic EL display device 50a. FIG. 4 is a cross-sectional view of an organic EL layer 16 included in the organic EL display panel 50a.

As shown in FIGS. 1 and 2, the organic EL display device 50a includes: a transparent resin substrate 10 provided as a base substrate; an organic EL element 18 provided (indirectly) over the resin substrate 10; and a sealing film 25a covering the organic EL element 18. Here, as shown in FIG. 1, in the organic EL display device 50a, the organic EL element 18 has a rectangular shape in a plan view, and accordingly, defines a rectangular display region D where images are displayed. The display region D includes a plurality of pixels arranged in a matrix. For example, each pixel includes a set of sub-pixels arranged adjacent to each other. The set of sub-pixels includes a sub-pixel for gradation display in red, a sub-pixel for gradation display in green, and a sub-pixel for gradation display in blue. As shown in FIG. 1, the organic EL display device 50a defines therein a non-display region N in the shape of a frame surrounding the display region D. As shown in FIG. 3, the organic EL display device 50a includes, between the resin substrate 10 and the organic EL element 18, a basecoat film 11, a plurality of TFTs 12, and an interlayer insulating film 13 which are sequentially stacked in a direction away from the resin substrate 10.

The first resin substrate 10 is a plastic substrate made of, for example, polyimide resin. The flexible, insulating, and transparent resin substrate is described as an example of the base substrate of this embodiment. Alternatively, the base substrate may be, for example, an insulating transparent glass substrate or an opaque, thin metal plate having electrical conductivity.

As shown in FIG. 3, the basecoat film 11 is provided on the resin substrate 10. Here, the basecoat film 11 is, for example, an inorganic insulating film such as a silicon dioxide film or a silicon nitride film.

As shown in FIG. 3, each of the TFTs 12 is a switching element provided on the basecoat film 11 for an associated one of the sub-pixels. Here, each TFT 12 includes, for example: a gate electrode provided on the basecoat film 11; a gate insulating film covering the gate electrode; a semiconductor layer provided over the gate insulating film and overlapping with the gate electrode; and source and drain electrodes provided over the semiconductor layer and facing each other. Note that each TFT 12 configured as a bottom gate TFT in this embodiment may be configured as a top gate TFT.

As shown in FIG. 3, the interlayer insulating film 13 covers each TFT 12, except for a portion of the drain electrode of the TFT 12. Here, the interlayer insulating film 13 is made of, for example, a transparent organic resin material such as acrylic resin.

The organic EL element 18 is arranged in the display region D, and includes a plurality of first electrodes 14, an edge cover 15, a plurality of organic EL layers 16, and a second electrode 17 which are sequentially provided over the interlayer insulating film 13, as shown in FIG. 3.

As shown in FIG. 3, the plurality of first electrodes 14 are arranged in a matrix on the interlayer insulating film 13 such that each first electrode 14 corresponds to a respective one of the plurality of sub-pixels. Here, as illustrated in FIG. 3, the first electrodes 14 are connected to the respective drain electrodes of the TFTs 12 via contact holes formed in the interlayer insulating film 13. The first electrodes 14 have the function of injecting holes (positive holes) into the organic EL layers 16. To increase the efficiency in injecting positive holes into the organic EL layers 16, the first electrodes 14 are preferably made of a material having a high work function. Non-limiting examples of materials for the first electrodes 14 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The first electrodes 14 may also be made of an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). Furthermore, the material for the first electrodes 14 may also be a conductive oxide such as tin oxide (SnO), zinc oxide (ZnO), indium tin oxide (ITO), and indium zinc oxide (IZO), for example. Moreover, the first electrodes 14 may be multilayers containing the above materials. Examples of the materials having a high work function include indium tin oxide (ITO) and indium zinc oxide (IZO).

The edge cover 15 is formed in a grid pattern to cover a peripheral portion of each first electrode 14 as shown in FIG. 3. Non-limiting examples of materials for the edge cover 15 include an inorganic film of silicon dioxide (SiO₂), silicon nitride (SiNx, where x is a positive number) such as Si₃N₄, and silicon oxynitride (SiNO), or an organic film of polyimide resin, acrylic resin, polysiloxane resin, and novolak resin.

As shown in FIG. 3, the organic EL layers 16 are each provided on a respective one of the first electrodes 14, and are arranged in a matrix so as to correspond to the sub-pixels. Here, as shown in FIG. 4, each organic EL layer 16 includes a positive hole injection layer 1, a positive hole transport layer 2, a light-emitting layer 3, an electron transport layer 4, and an electron injection layer 5, which are provided over the associated first electrode 14 in this order.

The positive hole injection layer 1 is also called an anode buffer layer, and has the function of bringing the energy levels of the first electrodes 14 and the organic EL layers 16 closer to each other and increasing efficiency in injection of positive holes from the first electrodes 14 into the organic EL layers 16. Here, non-limiting examples of materials for the positive hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The positive hole transport layer 2 has the function of increasing an efficiency in transportation of positive holes from the first electrodes 14 to the organic EL layers 16. Here, non-limiting examples of materials for the positive hole transport layer 2 include porphyrin derivatives, aromatic tertiary amine compounds, styryl amine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

When a voltage is applied from the first electrodes 14 and the second electrode 17, positive holes and electrons are injected from the first and second electrodes 14 and 17 into the light-emitting layer 3, in which the positive holes and the electrons are recombined with each other. The light-emitting layer 3 is made of a material having high luminous efficiency. Non-limiting examples of materials for the light-emitting layer 3 include metal oxinoid compounds (8-hydroxyquinoline metal complexes), naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bis(styryl)benzene derivatives, tris(styryl)benzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron transport layer 4 functions to efficiently move electrons to the light-emitting layer 3. Here, non-limiting examples of materials for the electron transport layer 4 includes, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 has the function of bringing the energy levels of the second electrode 17 and the organic EL layers 16 closer to each other and increasing efficiency in injection of electron from the second electrode 17 into the organic EL layers 16. This function contributes to reduction in the drive voltage of the organic EL element 18. The electron injection layer 5 may also be called a cathode buffer layer. Here, non-limiting examples of materials for the electron injection layer 5 include inorganic alkaline compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As shown in FIG. 3, the second electrode 17 covers the organic EL layers 16 and the edge cover 15. The second electrode 17 has the function of injecting electrons into the organic EL layers 16. To increase efficiency in injecting electrons into the organic EL layers 16, the second electrode 17 is preferably made of a material having a low work function. Here, non-limiting examples of materials for the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 17 may also be made of, for example, an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 17 may also contain, for example, a conductive oxide such as tin oxide (SnO), zinc oxide (ZnO), indium tin oxide (ITO), and indium zinc oxide (IZO). Moreover, the second electrode 17 may be multilayers containing the above materials. Non-limiting examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The sealing film 25a extends over the display region D and the non-display region N and covers the organic EL element 18. The sealing film 25a has the function of protecting the organic EL element 18 against moisture and oxygen. As shown in FIG. 2, the sealing film 25a includes a first barrier layer 19a, a first buffer layer 20a, a second barrier layer 21a, a second buffer layer 22a, and a third barrier layer 23a, which are stacked sequentially in a direction away from the organic EL element 18.

Non-limiting examples of materials for the first, second, and third barrier layers 19a, 21a, and 23a include inorganic films such as a silicon dioxide (SiO₂) film, an aluminum oxide (Al₂O₃) film, a film of silicon nitride (SiNₓ, where x is a positive number) such as Si₃N₄, and a silicon carbonitride (SiCN) film.

Non-limiting examples of materials for the first and second buffer layers 20a and 22a include organic films such as an acrylate film, a polyurea film, a parylene film, a polyimide film, and a polyamide film. Here, as shown in FIG. 2, the first buffer layer 20a includes, in its peripheral edge portion located in the non-display region N surrounding the organic EL element 18, a flat thin portion 20t having a thickness Tb (e.g., about 0.5 to 1.5 μm), which is smaller than the thickness Ta (e.g., about 2.5 μm) of the rest of the first buffer layer 20a located above the organic EL element 18. As shown in FIG. 2, the second buffer layer 22a includes, in its peripheral edge portion located in the non-display region N surrounding the organic EL element 18, a flat thin portion 22t having a thickness Td (e.g., about 0.5 to 1.5 μm), which is smaller than the thickness Tc (e.g., about 2.5 μm) of the rest of the second buffer layer 22a located above the organic EL element 18. Each of the first and second buffer layers 20a and 22a has, in its portion surrounding the organic EL element 18, a stepped cross-sectional shape of which the height decreases outwardly, as shown in FIG. 2. The thin portion 20t of the first buffer layer 20a and the thin portion 22t of the second buffer layer 22a surround the entire periphery of the organic EL element 18. As shown in FIG. 2, the thin portions 20t and 22t of the first and second buffer layers 20a and 22a overlap with each other in a plan view (i.e., as viewed in a substrate thickness direction). The thin portions 20t and 22t of the first and second buffer layers 20a and 22a each have a width raging from about 1.0 mm to about 3 mm, for example.

The organic EL display device 50a having the configuration described above is flexible, and capable of displaying an image by causing the light-emitting layer 3 of the organic EL layer 16 to appropriately emit light in each sub-pixel via the TFT 12.

The organic EL display device 50a of this embodiment is produced in the following manner. First, a basecoat film 11, TFTs 12, an interlayer insulating film 13, and an organic EL element 18 (including first electrodes 14, an edge cover 15, organic EL layers 16 (including a positive hole injection layer 1, a positive hole transport layer 2, a light-emitting layer 3, an electron transport layer 4, and an electron injection layer 5), and a second electrode 17) are formed, by a known method, over a surface of a resin substrate 10 made of, for example, polyimide resin. Next, organic and inorganic films are formed to cover the organic EL element 18 by chemical vapor deposition (CVD) or evaporation method, thereby forming a sealing film 25a. Here, during the deposition of the first and second buffer layers 20a and 22a forming part of the sealing film 25a, a film formation mask may be used to reduce the amount of material deposited in a peripheral edge portion located in a non-display region N surrounding the organic EL element 18. Alternatively, a layer once deposited to a uniform thickness may be dry-etched such that a peripheral portion thereof located in the non-display region N surrounding the organic EL element 18 is thinned down. In this way, the thin portions 20t and 22t are formed.

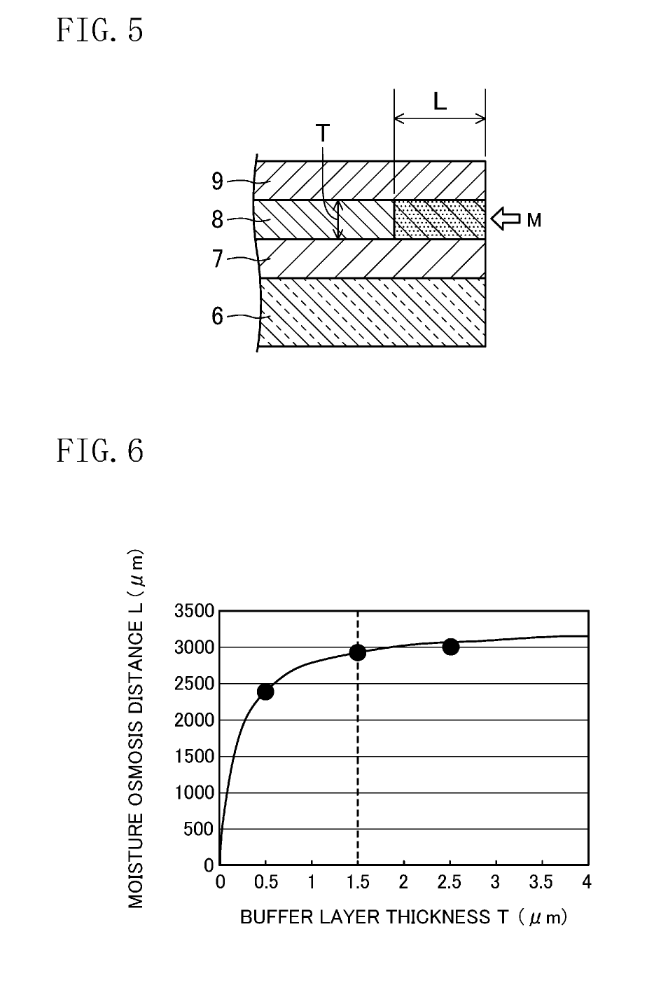

Next, an experiment which was actually conducted will be described. FIG. 5 is a cross-sectional view showing the model experiment on the organic EL display device 50a. FIG. 6 is a graph showing a relationship between a buffer layer thickness T and a moisture osmosis distance L, which was determined through the model experiment on the organic EL display device 50a.

As shown in FIG. 5, a SiNx film having a thickness of 0.5 μm, a SiCN film having a thickness of 0.5 μm, 1.5 μm, or 2.5 μm, and a SiNx film having a thickness of 0.5 μm were sequentially formed over a 0.7 mm thick glass substrate 6 by CVD. In this manner, three specimens each included a first barrier layer 7, a buffer layer 8, and a second barrier layer 9 were prepared, which differed in the thickness of the buffer layer 8.

The three specimens were allowed to stand in a constant temperature/humidity bath set at a temperature of 80° C. and a relative humidity of 85% for 336 hours. Thereafter, an end of the glass substrate 6 of each specimen was observed with a microscope to determine a moisture osmosis distance L. Specifically, as shown in FIG. 5, the length of an area of the buffer layer 8 which was discolored due to absorption of moisture M (i.e. the dotted area in the figure) was measured from the end surface of the glass substrate 6 at three different points, and the average of the measurements was taken to be determined as the moisture osmosis distance L.

FIG. 6 shows the results of the experiment. The results demonstrate that the moisture osmosis distance L increases in a logarithmic function manner with respect to the thickness T of the buffer layer 8, and that the moisture osmosis distance L steeply decreases when the thickness T of the buffer layer 8 is about 1.5 μm or less. Thus, it has been conjectured that in the three-layer stack including the first barrier layer 7, the buffer layer 8, and the second barrier layer 9, the speed at which the osmosis of moisture M progresses depends on the thickness of the buffer layer 8.

As can be seen, the organic EL display device 50a of this embodiment can provide the following advantages.

(1) The sealing film 25a, which covers the organic EL element 18 arranged in the display region D of the resin substrate 10, extends over the display region D and the non-display region N, and includes the first barrier layer 19a, a second barrier layer 21a, and a third barrier layer 23a that are each comprised of an inorganic film. The sealing film 25a also includes the first buffer layer 20a, which is comprised of an organic film and sandwiched between the adjacent first and second barrier layers 19a and 21a. The sealing film 25a further includes the second buffer layer 22a, which is comprised of an organic film and sandwiched between the adjacent second and third barrier layers 21a and 23a. The first buffer layer 20a includes, in its peripheral edge portion located in the non-display region N surrounding the organic EL element 18, a flat thin portion 20t of which the thickness Tb is smaller than the thickness Ta of the rest of the first buffer layer 20a located above the organic EL element 18. The second buffer layer 22a includes, in its peripheral edge portion located in the non-display region N surrounding the organic EL element 18, a flat thin portion 22t of which the thickness Td is smaller than the thickness Tc of the rest of the second buffer layer 22a located above the organic EL element 18. Thus, also in the peripheral edge portion located in the non-display region N surrounding the organic EL element 18, the thin portion 20t of the first buffer layer 20a is arranged between the first and second barrier layers 19a and 21a, and the thin portion 22t of the second buffer layer 22a is arranged between the second and third barrier layers 21a and 23a. As a result, stress caused by the first, second, and third barrier layers 19a, 21a, and 23a can be reduced by the first and second buffer layers 20a and 22a. This can reduce the risk of delamination of the sealing film 25a and similar inconveniences. In the peripheral edge portion located in the non-display region N surrounding the organic EL element 18, if foreign matter exists at any of the interfaces between the first, second, and third barrier layers 19a, 21a, and 23a, the interposition of the thin portion 20t of the first buffer layer 20a and the thin portion 22t of the second buffer layer 22a makes it difficult for the foreign matter to break through the first, second, and third barrier layers 19a, 21a, and 23a. Further, the thicknesses Tb and Td of the first and second buffer layers 20a and 22a in the peripheral edge portion located in the non-display region N surrounding the organic EL element 18 are smaller than the thicknesses Ta and Tc of the first and second buffer layers 20a and 22a above the organic EL element 18. This configuration can reduce the speed at which the osmosis of moisture M progresses from a peripheral end portion of the sealing film 25a. Thus, the configuration described above can reduce the risk of delamination of the sealing film 25a in its peripheral end portion, the risk of breaking through of the peripheral end portion of the sealing film 25a by foreign matter, and the risk of increase in the speed at which the osmosis of moisture M progresses from the peripheral end portion of the sealing film 25a, thereby enabling reduction of deterioration of the sealing capability of the peripheral end portion of the sealing film 25a.

(2) The thin portions 20t and 22t of the first and second buffer layers 20a and 22a each surround the entire periphery of the organic EL element 18. This configuration makes it possible to reduce the deterioration of the sealing capability of the peripheral end portion of the sealing film 25a along the entire periphery.

(3) The first and second buffer layers 20a and 22a include the thin portions 20t and 22t, respectively. This configuration can reduce the deterioration of the sealing capability of the peripheral end portion of the sealing film 25a more effectively than in a case where only one of the first and second buffer layers 20a and 22a includes a thin portion.

(4) The thin portions 20t and 22t of the first and second buffer layers 20a and 22a overlap with each other. Therefore, the thin portions 20t and 22t can be formed at a low cost if a single film formation mask or a single etching mask is shared.

(5) Each of the first and second buffer layers 20a and 22a has, in its peripheral edge portion located in the non-display region N surrounding the organic EL element 18, a stepped cross-sectional shape of which the height decreases outwardly. This configuration can reduce the width of the peripheral edge portion located in the non-display region N surrounding the organic EL element 18.

### Second Embodiment

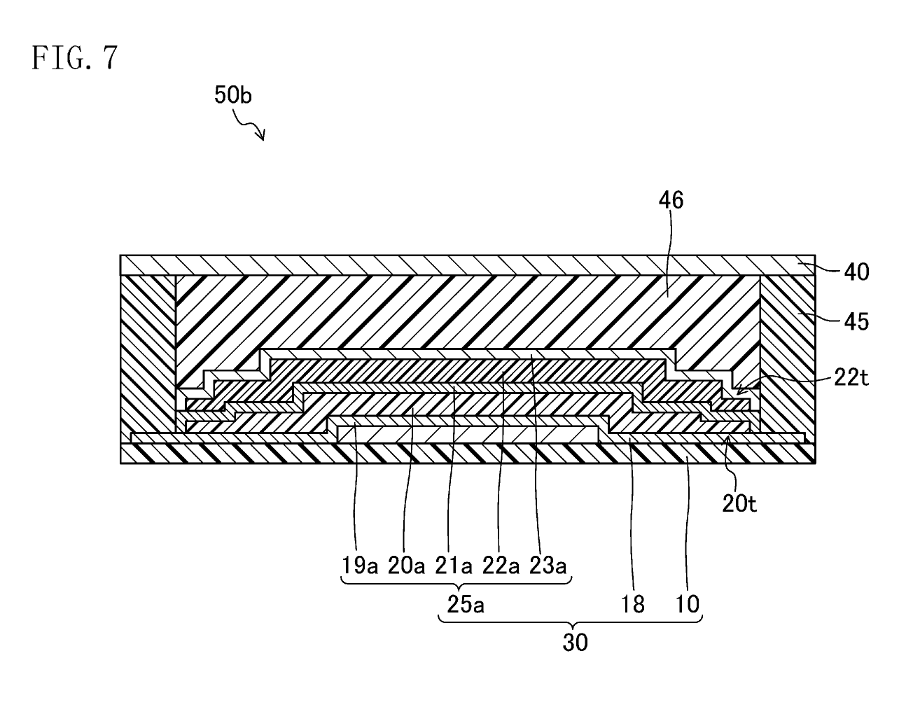

FIG. 7 is a plan view showing a schematic configuration for an organic EL display device 50b of this embodiment. In the embodiments below, components equivalent to those illustrated in FIGS. 1-6 are denoted by the same reference characters, and the detailed explanation thereof will be omitted.

In the first embodiment, the organic EL display devices 50a including no sealing substrate has been exemplified. In this embodiment, an organic EL display device 50b including a sealing substrate 40 is exemplified.

As shown in FIG. 7, the organic EL display device 50b includes: an element substrate 30 and the sealing substrate 40 facing each other; a frame-shaped sealing material 45 provided between the element substrate 30 and the sealing substrate 40; and a sealing resin layer 46 provided in a region surrounded by the sealing material 45 between the element substrate 30 and the sealing substrate 40.

As shown in FIG. 7, the element substrate 30 has substantially the same configuration as that of the organic EL display device 50a of the first embodiment. Note that although the element substrate 30 exemplified in this embodiment has substantially the same configuration as that of the organic EL display device 50a of the first embodiment, the element substrate 30 may alternatively be configured as an organic EL display device 50c of a third embodiment, which will be described later.

The sealing substrate 40 includes, for example, a resin substrate and a basecoat film provided on the resin substrate. Here, the resin substrate of the sealing substrate 40 has substantially the same configuration as that of the resin substrate 10 of the first embodiment. The basecoat film of the sealing substrate 40 has substantially the same configuration as that of the basecoat film 11 of the first embodiment.

The sealing material 45 is provided so as to bond a peripheral portion of the element substrate 30 to a peripheral portion of the sealing substrate 40. Non-limiting examples of materials for the sealing material 45 include epoxy resin, acrylic resin, polyimide resin, and phenol resin which are UV curable and/or thermosetting.

The sealing resin layer 46 functions as a getter (i.e., has the function of adsorbing oxygen, moisture, and other substances). Non-limiting examples of materials for the sealing resin layer 46 include epoxy resin and silicon resin which are thermosetting. Moreover, the sealing resin layer 46 contains, for example, a metal oxide such as calcium oxide (CaO), barium oxide (BaO), and aluminum oxide (Al₂O₃), and active carbon, silica gel, and zeolite.

The organic EL display device 50b having the configuration described above is flexible, and capable of displaying an image by causing the light-emitting layer 3 of the organic EL layer 16 to appropriately emit light in each sub-pixel via the TFT 12.

The organic EL display device 50b having the configuration described above can be produced in the following process.

First, a sealing resin is applied to a surface of the organic EL display device 50a produced by the production method according to the first embodiment, i.e., to a surface of the element substrate 30 by, for example, the dispending method, in a frame shape, and a filler resin is dropped onto and placed in the inside of the sealing resin.

Subsequently, the element substrate 30 on which the sealing resin and the filler resin have been arranged is bonded to the sealing substrate 40 in a reduced-pressure atmosphere. Thereafter, the reduced-pressure atmosphere is released, thereby applying a pressure to the outer surfaces of the element substrate 30 and the sealing substrate 40.

Further, for example, the sealing resin sandwiched between the element substrate 30 and the sealing substrate 40 is irradiated with UV light. Thereafter, the sealing resin and the filler resin are cured by heating the irradiated panel, thereby forming the sealing material 45 and the sealing resin layer 46.

As can be seen, the organic EL display device 50b of this embodiment can provide the following advantage (6), in addition to the advantages (1)-(5) described above.

(6) Provision of the sealing substrate 40 facing the element substrate 30, the sealing material 45 between the element substrate 30 and the sealing substrate 40, and the sealing resin layer 46 surrounded by the sealing material 45 between the element substrate 30 and the sealing substrate 40 can reduce deterioration of the organic EL element 18, and enhance the reliability of the organic EL display device 50b.

### Third Embodiment

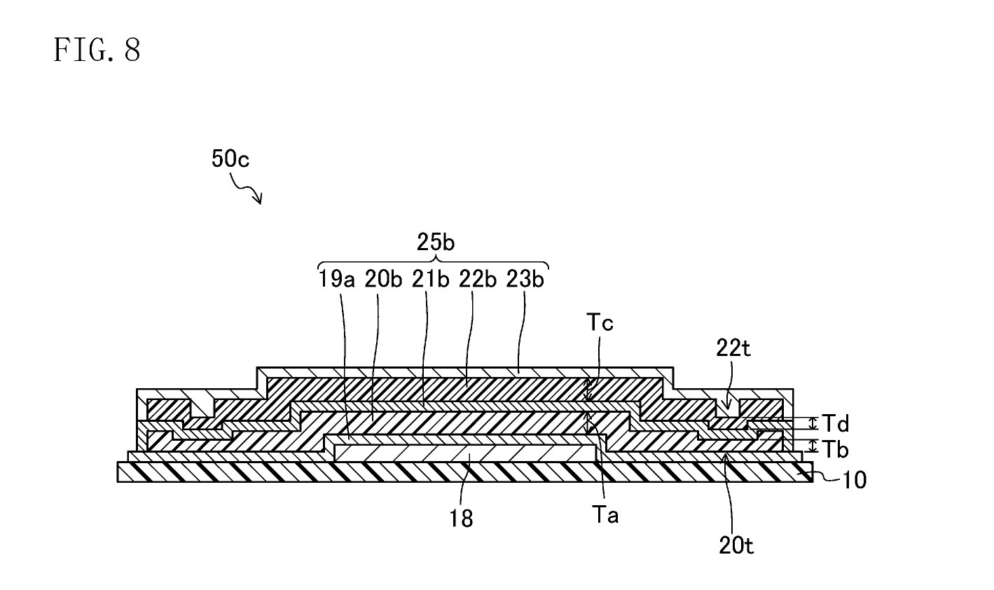

FIG. 8 is a cross-sectional view showing a schematic configuration for an organic EL display device 50c of this embodiment.

In the first and second embodiments, the organic EL display devices 50a and 50b each including the buffer layers having a stepped cross-sectional shape in its end portion have been exemplified. In this embodiment, an organic EL display device 50c is exemplified which includes buffer layers having a cross-sectional shape in which a thin portion forms a constriction.

As shown in FIG. 8, the organic EL display device 50c includes: a transparent resin substrate 10 provided as a base substrate; an organic EL element 18 provided (indirectly) over the resin substrate 10; and a sealing film 25b covering the organic EL element 18.

The sealing film 25b extends over a display region D and a non-display region N and covers the organic EL element 18. The sealing film 25b has the function of protecting the organic EL element 18 against moisture and oxygen. As shown in FIG. 8, the sealing film 25b includes a first barrier layer 19a, a first buffer layer 20b, a second barrier layer 21b, a second buffer layer 22b, and a third barrier layer 23b, which are staked sequentially in a direction away from the organic EL element 18.

Non-limiting examples of the materials for the second and third barrier layers 21b and 23b include inorganic films such as a silicon dioxide (SiO₂) film, an aluminum oxide (Al₂O₃) film, a film of silicon nitride (SiNₓ, where x is a positive number) such as Si₃N₄, and a silicon carbonitride (SiCN) film.

Non-limiting examples of the materials for the first and second buffer layers 20b and 22b include organic films such as an acrylate film, a polyurea film, a parylene film, a polyimide film, and a polyamide film. Here, as shown in FIG. 8, the first buffer layer 20b includes, in its peripheral edge portion located in the non-display region N surrounding the organic EL element 18, a flat thin portion 20t having a thickness Tb (e.g., about 0.5 to 1.5 μm) which is smaller than the thickness Ta (e.g., about 2.5 μm) of the rest of the first buffer layer 20b located above the organic EL element 18. As shown in FIG. 8, the second buffer layer 22b includes, in its peripheral edge portion located in the non-display region N surrounding the organic EL element 18, a flat thin portion 22t having a thickness Td (e.g., about 0.5 to 1.5 μm) which is smaller than the thickness Tc (e.g., about 2.5 μm) of the rest of the second buffer layer 22b located above the organic EL element 18. Thus, when viewed in section, each of the first and second buffer layers 20b and 22b has, in its peripheral edge portion located in the non-display region N surrounding the organic EL element 18, a constriction formed by the thin portion 20t or 22t, in other words, a groove having, for example, a U- or V-shaped cross section. The thin portions 20t and 22t of the first and second buffer layers 20b and 22b each surround the entire periphery of the organic EL element 18. As shown in FIG. 8, the thin portions 20t and 22t of the first and second buffer layers 20b and 22b overlap with each other in a plan view (i.e., as viewed in a substrate thickness direction). The thin portions 20t and 22t of the first second buffer layers 20b and 22b each has a width ranging from about 0.1 mm to about 3 mm.

The organic EL display device 50c having the configuration described above is flexible, and capable of displaying an image by causing the light-emitting layer 3 of the organic EL layer 16 to appropriately emit light in each sub-pixel via the TFT 12.

The organic EL display device 50c having the configuration above described can be produced by the production method of the organic EL display device 50a described in the first embodiment, and by changing the thickness arrangement in the formation of the inorganic and organic films.

As can be seen, the organic EL display device 50c of this embodiment can provide the following advantage (7), in addition to the advantages (1)-(4) described above.

The advantage (1) will be detailed below. The sealing film 25b, which covers the organic EL element 18 arranged in the display region D of the resin substrate 10, extends over the display region D and the non-display region N and includes the first barrier layer 19a, a second barrier layer 21b, and a third barrier layer 23b that are each comprised of an inorganic film. The sealing film 25b also includes the first buffer layer 20b, which is comprised of an organic film and sandwiched between the adjacent first and second barrier layers 19a and 21b. The sealing film 25b further includes the second buffer layer 22b, which is comprised of an organic film and sandwiched between the adjacent second and third barrier layers 21b and 23b. The first buffer layer 20b includes, in its peripheral edge portion located in the non-display region N surrounding the organic EL element 18, the flat thin portion 20t of which the thickness Tb is smaller than the thickness Ta of the rest of the first buffer layer 20b located above the organic EL element 18. The second buffer layer 22b includes, in its peripheral edge portion located in the non-display region N surrounding the organic EL element 18, the flat thin portion 22t of which the thickness Td is smaller than the thickness Tc of the rest of the second buffer layer 22b located above the organic EL element 18. Thus, also in the peripheral edge portion located in the non-display region N surrounding the organic EL element 18, the thin portion 20t of the first buffer layer 20b and the thin portion 22t of the second buffer layer 22b are arranged between the adjacent first and second barrier layers 19a and 21b, and between the adjacent second and third barrier layers 21b and 23b, respectively. As a result, stress caused by the first, second, and third barrier layers 19a, 21b, and 23b can be reduced by the first and second buffer layers 20b and 22b. This can reduce the risk of delamination of the sealing film 25b and similar inconveniences. In the peripheral edge portion located in the non-display region N surrounding the organic EL element 18, if foreign matter exists at any of the interfaces between the first, second, and third barrier layers 19a, 21b, and 23b, the interposition of the thin portion 20t of the first buffer layer 20b and the thin portion 22t of the second buffer layer 22b makes it difficult for the foreign matter to break through the first, second, and third barrier layers 19a, 21b, and 23b. Further, the thicknesses Tb and Td of the first and second buffer layers 20b and 22b in the peripheral edge portion located in the non-display region N surrounding the organic EL element 18 are smaller than the thicknesses Ta and Tc of the first and second buffer layers 20b and 22b above the organic EL element 18. This configuration can reduce the speed at which the osmosis of moisture M progresses from the peripheral end portion of the sealing film 25a. Thus, the configuration described above can reduce the risk of delamination of the sealing film 25b in the peripheral end portion, the risk of breaking through of the peripheral end portion of the sealing film 25b by foreign matter, and the risk of increase in the speed at which the osmosis of moisture M progresses from the peripheral end portion of the sealing film 25b, thereby enabling reduction of deterioration of the sealing capability of the peripheral end portion of the sealing film 25b.

The advantage (2) will be detailed below. The thin portions 20t and 22t of the first and second buffer layers 20b and 22b each surround the entire periphery of the organic EL element 18. This configuration makes it possible to reduce the deterioration of the sealing capability of the peripheral end portion of the sealing film 25b along the entire periphery.

The advantage (3) will be detailed below. The first and second buffer layers 20b and 22b include the thin portions 20t and 22t, respectively. This configuration can reduce the deterioration of the sealing capability of the peripheral end portion of the sealing film 25b more effectively than in a case where only one of the first and second buffer layers 20b and 22b has a thin portion.

The advantage (4) will be detailed below. The thin portions 20t and 22t of the first and second buffer layers 20b and 22b overlap with each other. Therefore, the thin portions 20t and 22t can be formed at a low cost if a single film formation mask or a single etching mask is shared.

(7) Each of the first and second buffer layers 20b and 22b has, in its peripheral edge portion located in the non-display region N surrounding the organic EL element 18, a cross-sectional shape in which the thin portion 20t or 22t forms a constriction. The constrictions formed by the thin portions 20t and 22t can reduce the speed at which the osmosis of moisture M progresses from the peripheral end portion of the sealing film 25b.

### Other Embodiments

In each of the above embodiments, the organic EL display device in which the thin portion of the first buffer layer overlaps with the thin portion of the second buffer layer has been exemplified. Alternatively, the present invention is applicable to an organic EL display device in which the thin portion of the first buffer layer does not overlap with the thin portion of the second buffer layer.

In each of the above embodiments, the organic EL display device in which each of the first and second buffer layers includes the thin portion has been exemplified. Alternatively, the present invention is applicable to an organic EL display device in which either one of the first and second buffer layers has the thin portion.

In each of the above embodiments, the organic EL display device including the five-layer sealing film that is comprised of the third barrier layer, the second buffer layer, the second barrier layer, the first buffer layer, and the first barrier layer has been exemplified. Alternatively, the present invention is applicable to an organic EL display device including a differently-structured sealing film in which a single buffer layer is sandwiched between two barrier layers, such as a three-layer sealing film comprised of, for example, a second barrier layer, a buffer layer, and a first barrier layer.

Moreover, in each of the above embodiments, the organic EL layer has been exemplified as a layer having a stacked structure of the five layers, namely, the positive hole injection layer, a positive hole transport layer, the light-emitting layer, the electron transport layer, and the electron injection layer. Alternatively, the organic EL layer may have a stacked structure of three layers including a positive hole injection and transport layer, a light-emitting layer, and an electron transport and injection layer, for example.

In each of the above embodiments, the organic EL display device in which the first electrode functions as the anode and the second electrode functions as the cathode has been exemplified. Alternatively, the present invention is applicable to an organic EL display device in which the stacked structure of the organic EL element is inverted, the first electrode functions as the cathode, and the second electrode functions as the anode.

In each of the above embodiments, the organic EL display device including the element substrate in which an electrode of the TFT connected to the first electrode is denoted as the drain electrode has been exemplified. Alternatively, the present invention is applicable to an organic EL display device including an element substrate in which the electrode of the TFT connected to the first electrode is called a source electrode.

### INDUSTRIAL APPLICABILITY

As can be seen from the foregoing description, the present invention is useful for an organic EL display device.

### DESCRIPTION OF REFERENCE CHARACTERS

D Display Region
N Non-Display Region
10 Resin Substrate (Base Substrate)
18 Organic EL Element
19a First Barrier Layer
20a, 20b First Buffer Layer
20t Thin Portion
21a, 21b Second Barrier Layer
22a, 22b Second Buffer Layer
22t Thin Portion
23a, 23b Third Barrier Layer
25a, 25b Sealing Film
30 Element Substrate
40 Sealing Substrate
45 Sealing Material
46 Sealing Resin Layer
50a-50c Organic EL Display Device

1. An organic EL display device comprising:
a base substrate defining thereon a display region configured to display an image, and a non-display region surrounding the display region;
an organic EL element provided in the display region of the base substrate; and
a sealing film extending over the display region and the non-display region and covering the organic EL element,
the sealing film including a plurality of barrier layers each comprised of an inorganic film, and a buffer layer comprised of an organic film and provided between adjacent two of the plurality of barrier layers, wherein
the buffer layer includes, in a peripheral edge portion of the buffer layer located in the non-display region surrounding the organic EL element, a flat thin portion which is thinner than the rest of the buffer layer located above the organic EL element.

2. The organic display device of claim 1, wherein
the thin portion surrounds an entire periphery of the organic EL element.

3. The organic display device of claim 1, wherein
the plurality of barrier layers include three different barrier layers,
the buffer layer includes two different buffer layers, and each of the two buffer layers includes the thin portion.

4. The organic display device of claim 3, wherein
the thin portions of the two buffer layers overlap with each other.

5. The organic display device of claim 1, wherein
the buffer layer has, in the peripheral edge portion of the buffer layer located in the non-display region surrounding the organic EL element, a stepped cross-sectional shape of which a height decreases outwardly.

6. The organic display device of claim 1, wherein
the buffer layer has, in the peripheral edge portion of the buffer layer located in the non-display region surrounding the organic EL element, a cross-sectional shape in which the thin portion forms a constriction.

7. The organic display device of claim 1, further comprising:
a sealing substrate facing the sealing film on the base substrate; and
a sealing material provided in a frame shape between an element substrate and the sealing substrate to bond the element substrate and the sealing substrate together, the element substrate including the base substrate, the organic EL element, and the sealing film.

8. The organic display device of claim 7, wherein
a sealing resin layer is provided in a region surrounded by the sealing material provided between the element substrate and the sealing substrate.

9. The organic display device of claim 1, wherein
the plurality of barrier layers is comprised of a first barrier layer, a second barrier layer, and a third barrier layer which are staked sequentially in a direction away from the organic EL element,
the buffer layer is comprised of a first buffer layer between the first and second barrier layers, and a second buffer layer between the second and third barrier layers, and
each of the first and second buffer layers has, in the peripheral edge portion of the buffer layer located in the non-display region surrounding the organic EL element, a cross-sectional shape in which the thin portion forms a constriction.

10. The organic display device of claim 9, wherein
each of the first and second buffer layers has a thin portion surrounding an entire periphery of the organic EL element.

11. The organic display device of claim 9, wherein
each of the first and second buffer layers has a thin portion, and the thin portions of the first and second buffer layers overlap with each other in a plan view.
